(19) United States
(12) Patent Application Publication
(10) Pub. No.: US 2009/0166719 A1
(43) Pub. Date: Jul. 2, 2009

(54) LDMOS SEMICONDUCTOR DEVICE MASK

(76) Inventor: Bong-Kil Kim, Bucheon-si (KR)

Correspondence Address: SHERR & VAUGHN, PLLC, 620 HERNDON PARKWAY, SUITE 200, HERNDON, VA, 20170, US

(21) Appl. No.: 12/344,555

(22) Filed: Dec. 28, 2008

(30) Foreign Application Priority Data
Dec. 28, 2007 (KR) 10-2007-0139994

(51) Int. Cl. H01L 29/78; H01L 29/423; H01L 21/336

(52) U.S. Cl. 257/327; 257/213; 438/228; 257/E29.128; 257/E29.264; 257/E21.421

(57) ABSTRACT

Embodiments relate to an LDMOS semiconductor device mask that may reduce current leakage under a gate-off condition. According to embodiments, an LDMOS semiconductor device mask may include a moat mask to define a moat region, an NDT mask to define an N drift region, a PDT mask to define a P drift region, and a gate mask to form a gate. According to embodiments, a PDT mask may be configured to expose a field region of a semiconductor device.

The present application claims priority under 35 U.S.C. 119 to Korean Patent Application No. 10-2007-0139994 (filed on Dec. 28, 2007), which is hereby incorporated by reference in its entirety.

### BACKGROUND

As semiconductor devices have become more highly integrated, development of a system with a single semiconductor chip may be increasing. Such a single chip system may be implemented for technology to integrate controllers, memories, and other circuits operating at low voltages into a single chip.

To achieve lighter and smaller systems, a circuit part to adjust power of a system, for example input and output terminals, and main functional circuits, may need to be integrated into a single chip. Input and output terminals, however, may not be realized as a low-voltage CMOS circuit because high voltages may be applied thereto. These may typically take a form of a high-voltage power transistor.

Accordingly, to reduce a size and/or weight of a system, it may be important to integrate input/output terminals of a power source and a controller into a single chip. A technology to enable this integration may be a power IC in which a high-voltage power transistor circuit and a low-voltage CMOS transistor circuit may be integrated into a single chip.

Such a power IC technology may be an improvement of a Vertical DMOS (VDMOS) device, such as a related art discrete power transistor, and may be a Lateral DMOS (LDMOS) device. In a LDMOS, a drain may be horizontally oriented, which may enable horizontal current flow. In addition, a drift region may be provided between a channel and a drain and may assure high-voltage breakdown.

An LDMOS device may be completed by ion implantation and photolithography processes, and the like. Ion implantation and photolithography processes may be implemented separately using independent mask layouts.

FIG. 1 is a drawing illustrating a related art LDMOS semiconductor device mask. Referring to FIG. 1, a LDMOS semiconductor device mask may include moat mask 10, which may define a moat region, NDT mask 12, which may define an N drift region, PDT mask 14, which may define a P drift region, and gate mask 20, which may be used to form a gate.

Referring to FIG. 2, in an LDMOS semiconductor device realized by the above-described related art LDMOS semiconductor device mask, current leakage of several μA may occur under a gate-off condition. As may be observed by a simulation of a doping profile from a field region to an active region, which may be a doping profile under an effect of phosphorus file-up by thermal oxidation and outward diffusion of boron and N/P junctions, phosphorus file-up and outward diffusion of boron may become worse as a thickness of an oxide layer in a field region increases. This may result in a current leakage under a gate-off condition (gate-off leakage). This result may also be observed from FIG. 3, illustrating that a sum of gate-off current and normal transistor current in a field region may exhibit a transistor current similar to data measured from an actual wafer.

Therefore, an LDMOS semiconductor device mask that may be capable of solving the above-described problems may be important.

### SUMMARY

Embodiments relate to a semiconductor device. Embodiments relate to an LDMOS semiconductor device mask that may reduce current leakage under a gate-off condition. Embodiments relate to an LDMOS semiconductor device mask that may reduce gate-off leakage.

According to embodiments, an LDMOS semiconductor device mask may include at least one of the following. A moat mask that may define a moat region. An NDT mask that may define an N drift region. A PDT mask that may define a P drift region. A gate mask that may form a gate. According to embodiments, the PDT mask may be configured to expose a field region of a semiconductor device.

### DRAWINGS

FIG. 1 is a drawing illustrating a related art LDMOS semiconductor device mask.

FIG. 2 is a drawing illustrating gate-off current leakage of a related art LDMOS semiconductor device.

FIG. 3 is a drawing illustrating transistor current of a related art LDMOS semiconductor device.

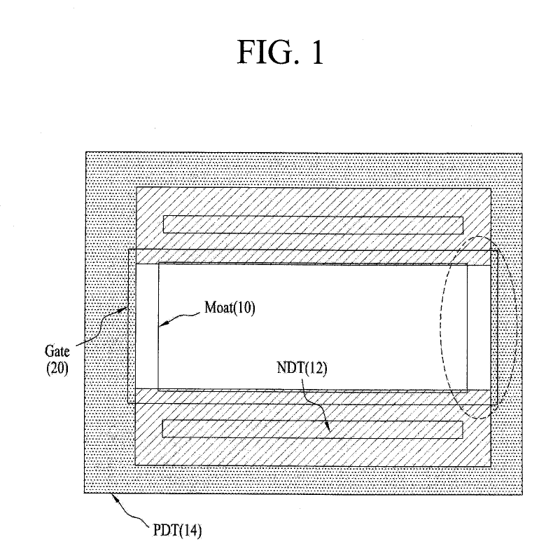

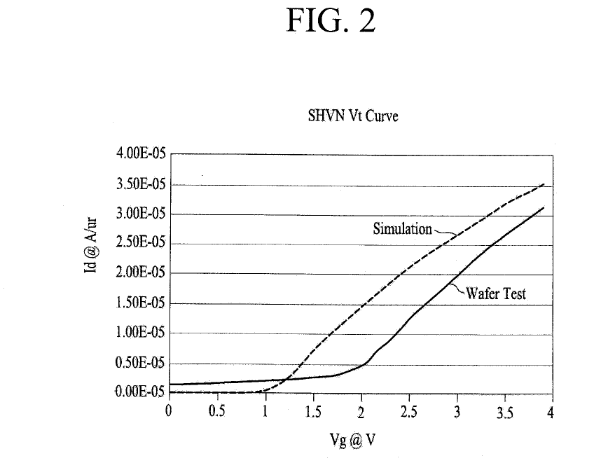

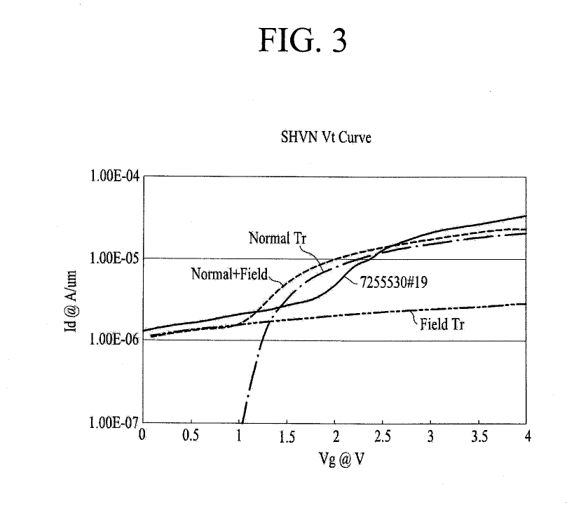

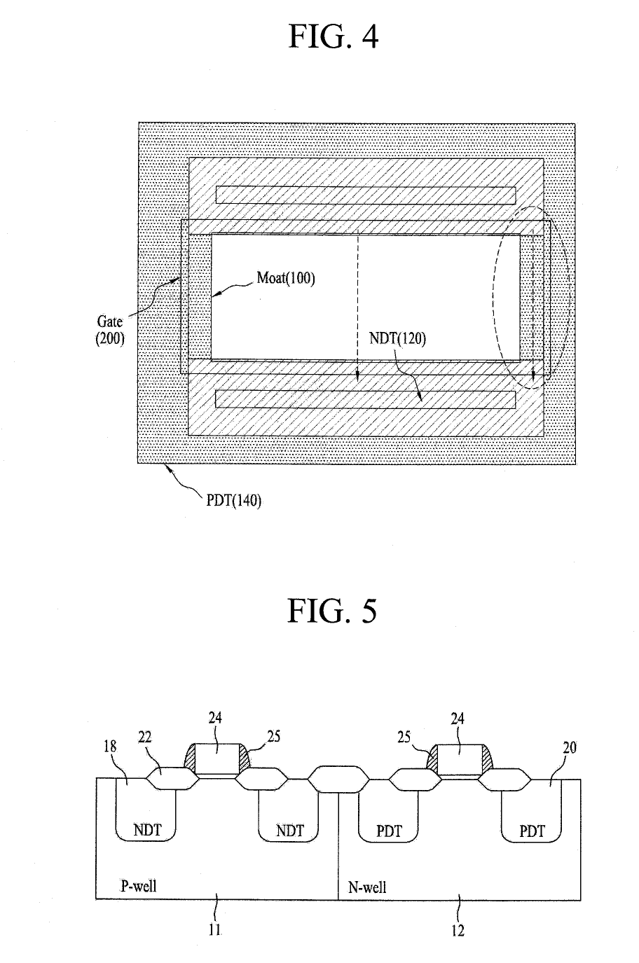

Example FIG. 4 is a drawing illustrating an LDMOS semiconductor device mask, according to embodiments.

Example FIG. 5 is a sectional view illustrating an LDMOS semiconductor device, according to embodiments.

### DESCRIPTION

Example FIG. 4 is a drawing illustrating an LDMOS semiconductor device mask, according to embodiments. Referring to example FIG. 4, an LDMOS semiconductor device mask according to embodiments may include moat mask 100, which may define a moat region, and NDT mask 120, which may define an N drift region. According to embodiments, an LDMOS semiconductor device mask may also include PDT mask 140, which may define a P drift region, and gate mask 200, which may form a gate. According to embodiments, PDT mask 140 may be formed to expose a field region of a semiconductor device.

According to embodiments, if boron B is implanted to define a P drift region, boron B may also be implanted into a field region. This may eliminate gate-off leakage from a field region.

Example FIG. 5 is a sectional view illustrating an LDMOS semiconductor device, according to embodiments. Referring to example FIG. 5, a P-type impurity and an N-type impurity may be implanted into a semiconductor substrate. This may define P-well 11 and N-well 12. According to embodiments, a buffer oxide layer and a nitride layer may be sequentially deposited on and/or over P-well 11 and N-well 12. According to embodiments, this may be performed by a coating process such as spin-coating, or the like, and may form a multilayer pad.

According to embodiments, photoresist (PR) pattern, which may define an NDT region using NDT mask 120, may be formed on and/or over a nitride layer on and/or over P-well 11. An etching process may be performed, and may use the PR pattern as an etching barrier layer. According to embodiments, a part of the deposited nitride layer may be selectively removed, and may thus form an NDT pattern, which may define the NDT region on and/or over P-well 11 and an oxide layer. According to embodiments, ion implantation may then be performed using the NDT pattern, and NDTs 18 may be formed in P-well 11. According to embodiments, an In-diffusion process may be implemented on and/or over NDTs 18 formed in P-well 11. This may form diffused NDTs 18. According to embodiments, PR pattern may be removed, for example by stripping.

According to embodiments, a PR pattern that may define a PDT region using PDT mask 140 may be formed on and/or over the nitride layer over N-well 12. According to embodiments, an etching process may be performed, and may use the PR pattern as an etching barrier layer. According to embodiments, a portion of a deposited nitride layer may be selectively removed. This may form a PDT pattern that may define a PDT region on and/or over N-well 12 and an oxide layer. According to embodiments, ion implantation may be performed using the PDT pattern. According to embodiments, PDTs 20 may be formed in N-well 12.

According to embodiments, an In-diffusion process may be implemented on and/or over PDTs 20 formed in N-well 12. This may form diffused PDTs 20. According to embodiments, the PR pattern may be removed, for example by stripping. According to embodiments, upon ion implantation to form the PDTs 20, boron B may be implanted. According to embodiments, boron may be implanted into a device isolation layer region because the PDT mask may expose the device isolation layer region.

According to embodiments, an insulating nitride layer may be deposited on and/or over a resultant structure. According to embodiments, a part of the deposited insulating nitride layer may be selectively removed using moat mask 100. This may form a moat pattern, which may define a moat region.

According to embodiments, a field region, which may be a device isolation layer 22, may be formed by an etching process using the moat pattern. According to embodiments, after removing the moat pattern, nitride layer and oxide layer, and the like remaining after an etching process, poly gates 24 and sidewalls 26 may be formed on and/or over P-well 11, which may contain NDTs 18, and N-well 12, which may contain PDTs 20. This may be done by a deposition process and an etching process using gate mask 200.

According to embodiments, an LDMOS semiconductor device manufactured using a PDT mask may enable ion implantation even below a device isolation layer. This may minimize or eliminate gate-off leakage from a device isolation layer, which may result in normal channel current.

According to embodiments, an LDMOS semiconductor device mask may have an improved configuration, which may expose a field region of an LDMOS semiconductor device. This may eliminate gate-off leakage in a field region of an LDMOS semiconductor device, which may result in a normal channel current.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A device, comprising:
a moat mask to define a moat region;
an NDT mask to define an N drift region; and
a PDT mask to define a P drift region, wherein the PDT mask is configured to expose a field region of a semiconductor device.

2. The device of claim 1, comprising a gate mask to form a gate.

3. The device of claim 1, wherein boron (B) is implanted into the field region to define the P drift region.

4. The device of claim 1, wherein the PDT mask is configured to enable ion implantation below the field region of the semiconductor device.

5. A method, comprising:
forming a P-well and an N-well in a semiconductor device;
depositing an oxide layer and a nitride layer over the P-well and the N-well, to form a multilayer pad;
forming an NDT in the P-well by ion implantation using an NDT mask over the nitride layer; and
forming a PDT in the N-well by ion implantation using a PDT mask over the nitride layer.

6. The method of claim 5, comprising:
forming a device isolation layer over the semiconductor device; and
forming poly gates and sidewalls over the P-well containing the NDT and the N-well containing the PDT using a gate mask.

7. The method of claim 6, wherein forming the device isolation layer comprises:
depositing an insulating nitride layer over the semiconductor device;
forming a moat pattern to define a moat region by selectively removing the insulating nitride layer; and
forming the device isolation layer using the moat pattern.

8. The method of claim 6, wherein the PDT mask is formed to expose the device isolation layer.

9. The method of claim 6, wherein the PDT mask is formed to expose a field region of the semiconductor device.

10. The method of claim 6, wherein forming the PDT comprises implanting impurity ions below the device isolation layer.

11. The method of claim 10, wherein the impurity comprises boron.

12. The method of claim 5, wherein forming the NDT in the P-well comprises:
forming a photoresist pattern to define an NDT region using the NDT mask over the nitride layer;
forming an NDT pattern to define the NDT region over the P-well and oxide layer by selectively removing the nitride layer using the photoresist pattern;
forming the NDT by ion implantation using the NDT pattern; and
forming a diffused NDT by performing In-diffusion over the NDT.

13. The method of claim 5, wherein forming the PDT in the N-well comprises:
forming a photoresist pattern to define a PDT region using the PDT mask over the nitride layer;
forming a PDT pattern to define the PDT region over the N-well and oxide layer by selectively removing the nitride layer using the photoresist pattern;
forming the PDT by ion implantation using the PDT pattern; and
forming a diffused PDT by performing In-diffusion over the PDT, wherein the PDT mask exposes a device isolation region.

14. A device, comprising:
a P-well and an N-well in a semiconductor device;
an oxide layer and a nitride layer over the P-well and N-well, forming a multilayer pad;
an NDT in the P-well; and
a PDT in the N-well.

15. The device of claim 14, comprising:
a device isolation layer over the semiconductor device; and
poly gates and sidewalls over the P-well containing the NDT and the N-well containing the PDT.

16. The device of claim 15, wherein a PDT mask is used to form the PDT, and wherein the PDT mask is configured to expose a field region of the semiconductor device.

17. The device of claim 16, wherein impurity ion implantation is performed below the device isolation layer when the PDT is formed.

18. The device of claim 16, wherein the poly gates and sidewalls are formed using a gate mask.

19. The device of claim 14, wherein the NDT region in the P-well is formed by ion implantation using an NDT mask over the nitride layer.

20. The device of claim 14, wherein the PDT in the N-well is formed by ion implantation using a PDT mask over the nitride layer, and wherein the PDT mask is configured to expose a device isolation region.
